(19) United States
(12) Patent Application Publication
(10) Pub. No.: US 2026/0322501 A1
(43) Pub. Date: Oct. 15, 2026

(54) AUTOMATIC GAIN CONTROL METHOD, MICROCONTROLLER UNIT, AND AUTOMATIC GAIN CONTROL SYSTEM

(71) Applicant: Eoptolink Technology Inc., Ltd, Chengdu (CN)

(72) Inventors: Xiaolei HUANG, Chengdu (CN); Han SONG, Chengdu (CN); Yu TAN, Chengdu (CN); Xingyi WU, Chengdu (CN); Pengfei HE, Chengdu (CN)

(73) Assignee: Eoptolink Technology Inc., Ltd, Chengdu (CN)

(21) Appl. No.: 19/462,944

(22) Filed: Jan. 28, 2026

Related U.S. Application Data
(63) Continuation of application No. PCT/CN2025/117415, filed on Aug. 28, 2025.

(30) Foreign Application Priority Data
Sep. 11, 2024 (CN) 202411271448.7

(51) Int. Cl. H04B 10/69

(52) U.S. Cl. CPC H04B 10/6931

(57) ABSTRACT

An automatic gain control method includes: first, after configuring and initializing the peak detection device in an optical module, and inserting the optical module into a target port of a network device, obtaining a peak value of the peak detection device at a preset frequency, wherein the peak value at the preset frequency comprises peak values at two frequencies; second, calculating an insertion loss value based on the peak value at the preset frequency; then, calculating an automatic gain control target value for the target port based on the insertion loss value; and finally, adjusting a gain of a linear driver with a goal of matching the automatic gain control target value. Based on the foregoing method, the problem of relatively low consistency of extinction ratios among channels in the prior art can be improved.

### CROSS-REFERENCE TO RELATED APPLICATIONS

This application is a continuation of International Application No. PCT/CN2025/117415, filed on Aug. 28, 2025, which claims priority to Chinese Patent Application No. 202411271448.7, filed on Sep. 11, 2024. The disclosures of the above-mentioned applications are hereby incorporated by reference in their entireties.

### TECHNICAL FIELD

This application relates to the field of communication technology, and in particular to an automatic gain control method, a microcontroller unit, and an automatic gain control system.

### BACKGROUND

In current data center architectures, the demand for high bandwidth increases with the development of supercomputing and artificial intelligence (AI) technologies. This drives data center operators towards higher-density, lower-latency, and more energy-efficient network solutions. In this context, Linear Pluggable Optics (LPO) transceivers have attracted widespread attention due to their advantages of low power consumption, low cost, and low latency. However, as the port density of network equipment such as high-speed switches used in data centers continues to increase, the requirements for LPO transceivers are also increasing. Since a single switch is typically equipped with only one serializer/deserializer (SerDes) chip, an increase in port density leads to significant variations in electrical insertion loss (IL) between different ports. Ports located closer to the center of the switch generally have shorter radio frequency (RF) traces, resulting in lower insertion loss; conversely, ports at the edge positions have longer RF traces, leading to higher insertion loss. This variation in insertion loss causes the same input signal to produce different output amplitudes at different ports, thereby affecting the extinction ratio (ER) in the optical domain. High insertion loss (HL) ports, in particular, may fail to meet communication standards due to insufficient extinction ratio, subsequently impacting the decision performance at the receiving end. In view of this, when an LPO transceiver is inserted into ports with different insertion loss characteristics, if the gain of the linear driver remains fixed, it will result in inconsistent output signal amplitudes across ports.

Currently, one approach to implementing automatic gain control (AGC) functionality is to monitor the output signal strength of the linear driver using a single-path peak detection (PKD) circuit. In practice, a PKD circuit is used to detect the signal strength at the output terminal of the driver. Then, a microcontroller unit (MCU) reads these PKD values in real time and dynamically adjusts the gain of the linear driver accordingly to maintain the stability of the PKD values, thereby ensuring consistency in the driver output.

However, this method has certain limitations. For example, the impact of insertion loss on signals of different frequencies is not uniform. For example, high-frequency signals often experience greater attenuation than low-frequency signals. In high-speed data transmission environments, signals contain multiple components ranging from low to high frequencies. Therefore, relying solely on the PKD value of a single frequency band (e.g., 20 GHz) cannot accurately reflect the actual insertion loss situation. This means that if the AGC system relies solely on the PKD value of a single frequency band to adjust the gain, the system's extinction ratio (ER) may still exhibit significant differences when facing ports with different insertion loss characteristics. Consequently, even after AGC adjustments, signal quality may still fail to achieve ideal consistency under varying insertion loss conditions.

### SUMMARY

In view of this, the purpose of this application is to provide an automatic gain control method, a microcontroller unit, and an automatic gain control system, so as to improve the problem of relatively low consistency in extinction ratios among channels.

To achieve the above purpose, this application adopts the following technical solution.

An automatic gain control method is applied to a microcontroller unit in an automatic gain control system, the automatic gain control system comprises a peak detection device, the automatic gain control method comprises:
after configuring and initializing the peak detection device in an optical module, and inserting the optical module into a target port of a network device, obtaining a peak value of the peak detection device at a preset frequency, wherein the peak value at the preset frequency comprises peak values at two frequencies;
calculating an insertion loss value based on the peak value at the preset frequency;
calculating an automatic gain control target value for the target port based on the insertion loss value; and
adjusting a gain of a linear driver with a goal of matching the automatic gain control target value.

Optionally, in the automatic gain control method, the peak detection device comprises a first peak detection unit and a second peak detection unit, and the step of after configuring and initializing the peak detection device in an optical module, and inserting the optical module into a target port of a network device, obtaining a peak value of the peak detection device at a preset frequency comprises:
after configuring and initializing the peak detection device in the optical module and inserting the optical module into the target port of the network device, obtaining a first peak value by the first peak detection unit detecting a low-frequency signal, and obtaining a second peak value by the second peak detection unit detecting a high-frequency signal.

Optionally, in the automatic gain control method, a cutoff frequency of the first peak detection unit is 1 GHZ, and the step of obtaining a first peak value by the first peak detection unit detecting a low-frequency signal comprises:
obtaining the first peak value by detecting a low-frequency signal of 1 GHz through the first peak detection unit.

Optionally, in the automatic gain control method, a center frequency of the second peak detection unit is 20 GHz, and the step of obtaining a second peak value by the second peak detection unit detecting a high-frequency signal comprises:
obtaining the second peak value by detecting a high-frequency signal of 20 GHz through the second peak detection unit.

Optionally, in the automatic gain control method, the step of calculating an insertion loss value based on the peak value at the preset frequency comprises:
determining a normalized difference between the peak values at the two frequencies; and
determining the insertion loss value based on the normalized difference.

Optionally, in the automatic gain control method, the step of determining a normalized difference between the peak values at the two frequencies comprised in the peak value at the preset frequency comprises:
determining a difference value between the peak values at the two frequencies comprised in the peak value at the preset frequency; and
determining a ratio of the difference value to the peak value at a higher frequency among the two frequencies comprised in the peak value at the preset frequency, so as to obtain the normalized difference between the peak values at the two frequencies.

Optionally, in the automatic gain control method, the step of calculating an automatic gain control target value for the target port based on the insertion loss value comprises: obtaining a predetermined automatic gain control reference value; and
determining the automatic gain control target value of the target port based on the automatic gain control reference value and the insertion loss value.

Optionally, in the automatic gain control method, the step of determining the automatic gain control target value of the target port based on the automatic gain control reference value and the insertion loss value comprises:
determining a target parameter based on a predetermined first adjustment coefficient, a predetermined second adjustment coefficient, and the insertion loss value, wherein the first adjustment coefficient and the second adjustment coefficient are used respectively as a weighting factor and a bias factor of the insertion loss value to calculate the target parameter; and
determining the automatic gain control target value of the target port based on the automatic gain control reference value and the target parameter, wherein the target parameter serves as a weighting factor of the automatic gain control reference value to calculate the automatic gain control target value.

Optionally, in the automatic gain control method, the step of adjusting a gain of a linear driver with a goal of matching the automatic gain control target value comprises:
adjusting the gain of the linear driver based on the automatic gain control target value;
obtaining a new peak value of the peak detection device at the preset frequency;
calculating a new insertion loss value according to the new peak value at the preset frequency; and
determining whether the gain adjustment of the linear driver is completed based on the new insertion loss value.

Based on the above, this application also provides a microcontroller unit, and the microcontroller unit is configured to execute the automatic gain control method described above.

Based on the above, this application also provides an automatic gain control system, the automatic gain control system comprises a microcontroller unit and a peak detection device, wherein the peak detection device is configured to detect peak values of a target port at two frequencies, and the microcontroller unit is configured to execute the automatic gain control method based on the peak values at the two frequencies.

Optionally, in the automatic gain control system, the peak detection device comprises a photoelectric converter, a first peak detection unit, and a second peak detection unit;
wherein, input terminals of the first peak detection unit and the second peak detection unit are respectively electrically connected to output terminals of the photoelectric converter, the first peak detection unit is configured to detect a low-frequency signal in an electrical signal output by the photoelectric converter converting an optical signal of the target port, so as to obtain a first peak, and the second peak detection unit is configured to detect a high-frequency signal in the electrical signal output by the photoelectric converter converting the optical signal of the target port, so as to obtain a second peak.

Optionally, in the automatic gain control system, the first peak detection unit comprises a low-pass filter and a first detection chip; and
the low-pass filter is configured to allow a low-frequency signal to pass, and the first detection chip is configured to detect a peak value of the low-frequency signal.

Optionally, in the automatic gain control system, the second peak detection unit comprises a band-pass filter and a second detection chip; and
the band-pass filter is configured to allow a high-frequency signal to pass, and the second detection chip is configured to detect a peak value of the high-frequency signal.

### BRIEF DESCRIPTION OF THE DRAWINGS

FIG. 1 is a circuit diagram of a peak detection device according to an embodiment of this application.

FIG. 2 is a schematic flowchart of an automatic gain control method according to an embodiment of this application.

FIG. 3 is a schematic diagram illustrating extinction ratio data of all ports of a switch after using the automatic gain control method according to an embodiment of this application.

### DETAILED DESCRIPTION OF THE EMBODIMENTS

In order to make the objectives, technical solutions, and advantages of the embodiments of this application clearer, the technical solutions of the embodiments of this application are described in detail below with reference to the accompanying drawings. Obviously, the described embodiments are only a part of the embodiments of this application, and not all of them. The components of the embodiments of this application described and shown in the accompanying drawings can generally be arranged and designed in various configurations.

Therefore, the following detailed description of the embodiments of this application provided in the accompanying drawings is not intended to limit the scope of the claimed application, but merely to illustrate selected embodiments of this application. Based on the embodiments of the present disclosure, all other embodiments obtained by those skilled in the art without inventive effort shall fall within the scope of protection of this application.

The embodiments of this application provide an automatic gain control system. The automatic gain control system may include a microcontroller unit and a peak detection device.

Specifically, the peak detection device is configured to detect the peak values of a target port at two frequencies, and the microcontroller unit is configured to execute an automatic gain control method based on the peak values at the two frequencies to adjust the gain of a linear driver. The target port can be a port of a network device such as a switch.

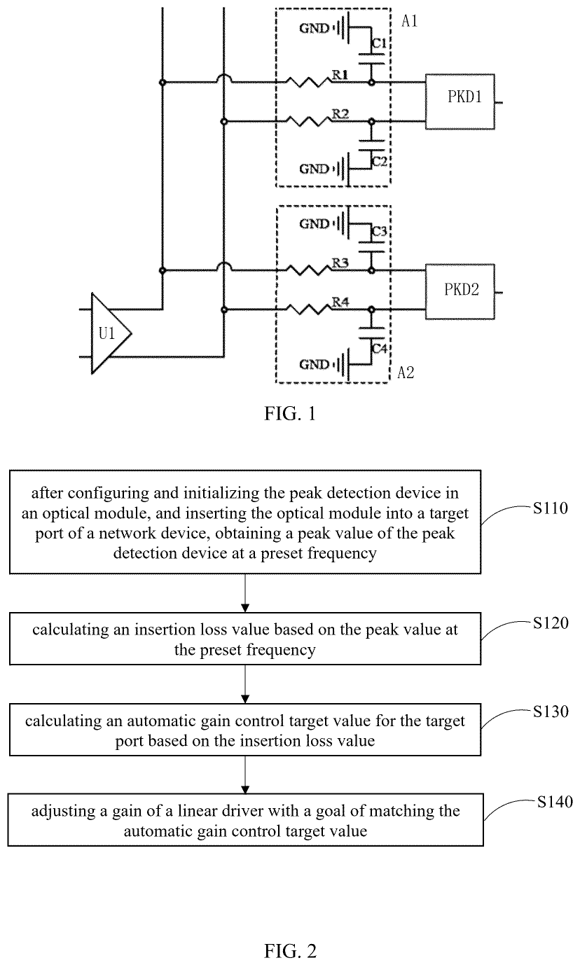

Optionally, in an alternative embodiment, as shown in FIG. 1, the peak detection device may include a photoelectric converter U1, a first peak detection unit, and a second peak detection unit.

Specifically, the input terminals of the first peak detection unit and the second peak detection unit are respectively electrically connected to the output terminals of the photoelectric converter U1. The first peak detection unit is configured to detect a low-frequency signal in an electrical signal output by the photoelectric converter U1 after converting an optical signal of the target port, obtaining a first peak value. The second peak detection unit is configured to detect a high-frequency signal in the electrical signal output by the photoelectric converter U1 after converting the optical signal from the target port, obtaining a second peak value.

That is, after the photoelectric converter U1 converts the optical signal from the target port into the electrical signal, the first peak detection unit detects the peak value of the low-frequency signal in the electrical signal to obtain the first peak value, and the second peak detection unit detects the peak value of the high-frequency signal in the electrical signal to obtain the second peak value.

Optionally, in an alternative embodiment, the first peak detection unit may include a low-pass filter A1 and a first detection chip PKD1.

Specifically, the low-pass filter A1 may be configured to pass low-frequency signals, and the first detection chip PKD1 may be configured to detect the peak value of the low-frequency signal. That is, for the electrical signal output from the photoelectric converter U1, the low-pass filter A1 filters the signal and outputs the low-frequency signal to the first detection chip PKD1, the first detection chip PKD1 then detects the peak value of the low-frequency signal to obtain the first peak value.

Optionally, in an alternative embodiment, the second peak detection unit may include a band-pass filter A2 and a second detection chip PKD2.

Specifically, the band-pass filter A2 may be configured to pass high-frequency signals, and the second detection chip PKD2 may be configured to detect the peak value of the high-frequency signal. That is, for the electrical signal output from the photoelectric converter U1, the band-pass filter A2 filters the signal and outputs the high-frequency signal to the second detection chip PKD2, the second detection chip PKD2 then detects the peak value of the high-frequency signal to obtain the second peak value. Additionally, it should be noted that the first detection chip PKD1 and the second detection chip PKD2 may be any chip or circuit capable of detecting the peak value of the signal, without specific limitations or descriptions here.

Optionally, in an alternative embodiment, the low-pass filter A1 may include a first resistor R1, a second resistor R2, a first capacitor C1, and a second capacitor C2.

Specifically, a first end of the first resistor R1 is connected to a first output terminal of the photoelectric converter U1, and a second end of the first resistor R1 is connected to a first input terminal of the first detection chip PKD1. A first end of the second resistor R2 is connected to a second output terminal of the photoelectric converter U1, and a second end of the second resistor R2 is connected to a second input terminal of the first detection chip PKD1. A first end of the first capacitor C1 is connected to the second end of the first resistor R1, and a second end of the first capacitor C1 is grounded. A first end of the second capacitor C2 is connected to the second end of the second resistor R2, and a second end of the second capacitor C2 is grounded.

Optionally, in an alternative embodiment, the first resistor R1, the second resistor R2, the first capacitor C1, and the second capacitor C2 can be configured to allow low-frequency signals around 1 GHz to pass through while suppressing high-frequency signals above 1 GHz. Accordingly, the first detection chip PKD1 is configured to detect the peak value of the low-frequency signal around 1 GHz.

Optionally, in an alternative embodiment, the bandpass filter A2 may include a third resistor R3, a fourth resistor R4, a third capacitor C3, and a fourth capacitor C4.

Specifically, a first end of the third resistor R3 is connected to the first output terminal of the photoelectric converter U1, and a second end of the third resistor R3 is connected to the first input terminal of the second detection chip PKD2. A first end of the fourth resistor R4 is connected to the second output terminal of the photoelectric converter U1, and a second end of the fourth resistor R4 is connected to the second input terminal of the second detection chip PKD2. A first end of the third capacitor C3 is connected to the second end of the third resistor R3, and a second end of the third capacitor C3 is grounded. A first end of the fourth capacitor C4 is connected to the second end of the fourth resistor R4, and a second end of the fourth capacitor C4 is grounded.

Optionally, in an alternative embodiment, the third resistor R3, the fourth resistor R4, the third capacitor C3, and the fourth capacitor C4 may be configured to allow high-frequency signals around 20 GHz to pass through, while suppressing signals below 1 GHz and above 20 GHz. Accordingly, the second detection chip PKD2 is configured to detect the peak value of the high-frequency signal around 20 GHz.

This application further provides a microcontroller unit. The microcontroller unit can be applied to the aforementioned automatic gain control system, and the automatic gain control system can be configured to perform the automatic gain control method to adjust the gain of a linear driver. Exemplarily, the microcontroller unit can acquire the peak values at the two frequencies obtained by the peak detection device detecting the target port included in the automatic gain control system, and determine an automatic gain control target value based on the peak values at the two frequencies. The microcontroller unit then adjusts the gain of the linear driver with the aim of matching the automatic gain control target value, thereby accomplishing automatic control of the gain.

Referring to FIG. 2, the present application further provides an automatic gain control method. The automatic gain control method can be applied to the aforementioned microcontroller unit, and thus, the steps included in the automatic gain control method can be implemented by the microcontroller unit. The details of each step are as follows.
Step S110: after configuring and initializing a peak detection device in an optical module and inserting the optical module into a target port of a network device, obtaining a peak value of the peak detection device at a preset frequency.

In this embodiment, after configuring and initializing the peak detection device in the optical module and inserting the optical module into the target port of the network device (such as a switch), the microcontroller unit can obtain the peak value of the peak detection device at the preset frequency. The peak value at the preset frequency includes peak values at two frequencies, which refer to the peak values obtained by the peak detection device by detecting signals of the target port at the two respective frequencies. It should also be noted that the optical module may include the aforementioned automatic gain control system. Furthermore, when inserting the optical module into the target port of the network device, it is necessary to ensure a normal electrical connection between the optical module and the target port.
Step S120: calculating an insertion loss value based on the peak value at the preset frequency.

In this embodiment, after obtaining the peak value at the preset frequency, the microcontroller unit can calculate the insertion loss value based on the peak value at the preset frequency. That is, the insertion loss value can be calculated based on the peak values at two frequencies.
Step S130: calculating an automatic gain control target value for the target port based on the insertion loss value.

In this embodiment, after calculating the insertion loss value, the microcontroller unit can calculate the automatic gain control target value for the target port based on the insertion loss value, wherein the automatic gain control target value refers to the target gain value.
Step S140: adjusting a gain of a linear driver with a goal of matching the automatic gain control target value.

In this embodiment, after calculating the automatic gain control target value, the microcontroller unit can adjust the gain of the linear driver to match the automatic gain control target value.

It should be noted that, with respect to the above Step S110, the specific manner in which the peak values are obtained by the peak detection device at the preset frequencies is not limited and may be selected according to actual requirements.

For example, in an alternative embodiment, the peak detection device may include a first peak detection unit and a second peak detection unit. Based on this, the step S110 may include the following:

After configuring and initializing the peak detection device in the optical module, and inserting the optical module into the target port of the network device, obtaining a first peak value by the first peak detection unit detecting a low-frequency signal, and obtaining a second peak value by the second peak detection unit detecting a high-frequency signal. Thus, peak values at two frequencies, including the first peak value and the second peak value, can be obtained respectively.

Optionally, in an alternative embodiment, the cutoff frequency of the first peak detection unit may be 1 GHz. Based on this, the step of obtaining the first peak value by the first peak detection unit detecting the low-frequency signal may include the following:
obtaining the first peak value by detecting the low-frequency signal of 1 GHz through the first peak detection unit; exemplarily, after the low-pass filter A1 included in the first peak detection unit filters and outputs the low-frequency signal, the first detection chip PKD1 included in the first peak detection unit detects the peak value of the low-frequency signal to obtain the first peak value. Thus, the microcontroller unit can obtain the first peak value from the output terminal of the first detection chip PKD1.

It should be noted that in other embodiments, the cutoff frequency of the first peak detection unit can also be other low-frequency values, such as 2 GHz, 3 GHZ, etc.

Optionally, in an alternative embodiment, the center frequency of the second peak detection unit can be 20 GHz. Based on this, the step of obtaining the second peak value obtained by the second peak detection unit by the second peak detection unit detecting the high-frequency signal may include the following:
obtaining the second peak value by detecting a high-frequency signal of 20 GHz through the second peak detection unit; exemplarily, after the bandpass filter A2 of the second peak detection unit filters and outputs the high-frequency signal, the second detection chip PKD2 of the second peak detection unit detects the peak value of the high-frequency signal to obtain the second peak value. Thus, the microcontroller unit can obtain the second peak value from the output terminal of the second detection chip PKD2.

It should be noted that in other embodiments, the center frequency of the second peak detection unit can also be other high-frequency values, such as 19 GHz, 21 GHZ, etc.

Regarding the step S120, it should be noted that the specific method for calculating the insertion loss value based on the peak value at the preset frequency is not limited and can be selected according to actual requirements.

For example, in an alternative embodiment, considering that signals of different frequencies have different losses along the transmission path, the difference between the peak values of two different frequency domains can be used to reflect the change in insertion loss, making the insertion loss determined based on the peak value have higher reliability. Accordingly, the step S120 includes the following:
firstly, determining a normalized difference between the peak values at the two frequencies; and
secondly, determining the insertion loss value based on the normalized difference;
exemplarily, the normalized difference can be used as the insertion loss value.

Optionally, in an alternative embodiment, the step of determining a normalized difference between the peak values at the two frequencies comprised in the peak value at the preset frequency may further include the following:
First, determining a difference value between the peak values at the two frequencies comprised in the peak value at the preset frequency; exemplarily, the difference between the peak value at the larger frequency and the peak value at the smaller frequency among the two peak values included in the peak value at the preset frequency can be calculated, such as the difference between the second peak value and the first peak value described above;
Second, determining a ratio of the difference value to the peak value at a higher frequency among the two frequencies comprised in the peak value at the preset frequency, so as to obtain the normalized difference between the peak values at the two frequencies.

Optionally, in an alternative embodiment, the above-mentioned normalized difference (or insertion loss value) can be calculated as follows:

$$IL = \frac{20 G PKD - 1 G PKD}{20 G PKD} ;$$

wherein, IL represents the normalized difference (or insertion loss value); 20G PKD represents a signal peak detection value at a frequency of 20 GHz (such as the second peak value described above); 1G PKD represents a signal peak detection value at a frequency of 1 GHz (such as the first peak value described above).

It should be noted that at high frequencies, signals are more susceptible to transmission path losses, resulting in higher insertion losses; at low frequencies, signals experience less loss, leading to relatively lower insertion losses. The insertion loss value reflects the degree of attenuation of the high-frequency signal relative to its own strength. Since 1G PKD is relatively stable when insertion loss changes, this ratio can effectively reflect changes in insertion loss. The insertion loss is determined based on the peak difference between high-frequency and low-frequency signals, and the gain of the linear driver is adjusted accordingly to achieve consistent signal quality under different insertion loss conditions.

Regarding the step S130, it should be noted that the specific method for calculating the automatic gain control target value for the target port based on the insertion loss value is not limited and can be selected according to actual needs.

For example, in an alternative embodiment, to ensure the reliability of the determined automatic gain control target value, the step S130 may further include the following.

Firstly, obtaining a predetermined automatic gain control reference value; exemplarily, the automatic gain control reference value can be an optimal gain value determined in advance through testing, for example, it can be determined based on the extinction ratio.

Secondly, determining the automatic gain control target value of the target port based on the automatic gain control reference value and the insertion loss value. That is, the automatic gain control reference value, which represents the optimal gain, can be adjusted or mapped by using the calculated insertion loss value to obtain the automatic gain control target value.

Optionally, in an alternative embodiment the step of determining the automatic gain control target value of the target port based on the automatic gain control reference value and the insertion loss value may further include the following.

Firstly, determining a target parameter based on a predetermined first adjustment coefficient, a predetermined second adjustment coefficient, and the insertion loss value, wherein the first adjustment coefficient and the second adjustment coefficient are used respectively as a weighting factor and a bias factor of the insertion loss value to calculate the target parameter. For example, the insertion loss value can be multiplied by the first adjustment coefficient, and the multiplication result can be added to the second adjustment coefficient to obtain the target parameter.

Secondly, determining the automatic gain control target value of the target port based on the automatic gain control reference value and the target parameter, wherein the target parameter serves as a weighting factor of the automatic gain control reference value to calculate the automatic gain control target value. For example, the target parameter can be multiplied by the automatic gain control reference value to obtain the automatic gain control target value.

Optionally, in an alternative embodiment, the automatic gain control target value can be calculated as follows:

$$AGCtarget = AGCref * ( 1 + k * IL ) ;$$

wherein, AGCtarget represents the automatic gain control target value; AGCref represents the automatic gain control reference value; k represents the first adjustment coefficient, 1 represents the second adjustment coefficient; and IL represents the insertion loss value. It should be noted that the specific value of k can be obtained through fitting experimental data. Therefore, for different brands of switches, only different k values need to be written to adapt to different switches. For example, for a Tomahawk 5 switch, the specific value of k can be 0.85.

Regarding the step S140, it should be noted that the specific method of adjusting the gain of the linear driver to match the automatic gain control target value is not limited and can be selected according to actual needs.

For example, in an alternative embodiment, to achieve effective adjustment and control of the gain, the step S140 may further include the following:
firstly, adjusting the gain of the linear driver based on the automatic gain control target value;
secondly, obtaining a new peak value of the peak detection device at the preset frequency;
then, calculating a new insertion loss value according to the new peak value at the preset frequency; and
further, determining whether the gain adjustment of the linear driver is completed based on the new insertion loss value. For example, if a difference between the new insertion loss value and the automatic gain control target value is less than a set threshold, it can be considered that the actual gain has approached the automatic gain control target value, and therefore, the gain adjustment can be determined to be complete; conversely, if the difference between the new insertion loss value and the automatic gain control target value is not less than the set threshold, it can be considered that the actual gain has not approached the automatic gain control target value, and therefore, the gain adjustment can be determined to be incomplete. Thus, the gain of the linear driver can continue to be adjusted until the difference between the current insertion loss value and the automatic gain control target value is less than the set threshold.

In other words, based on the automatic gain control target value, the gain of the linear driver is adjusted, and this adjustment is repeated through continuous peak detection and feedback mechanisms until the actual gain matches the automatic gain control target value, i.e., the difference between the actual gain and the target value falls within a specified threshold range.

For example, adjusting the linear driver's gain by a control signal based on the automatic gain control target value can be achieved by sending an adjustment command to the linear driver to set its gain close to the automatic gain control target value. Then, the peak detection device is restarted to continuously monitor the peak values of the high-frequency and low-frequency signals. A new peak detection result is compared with the automatic gain control target value. If the actual gain does not match the automatic gain control target value, continuous peak detection and feedback adjustments are made to gradually approach the automatic gain control target value until the actual gain matches the automatic gain control target value.

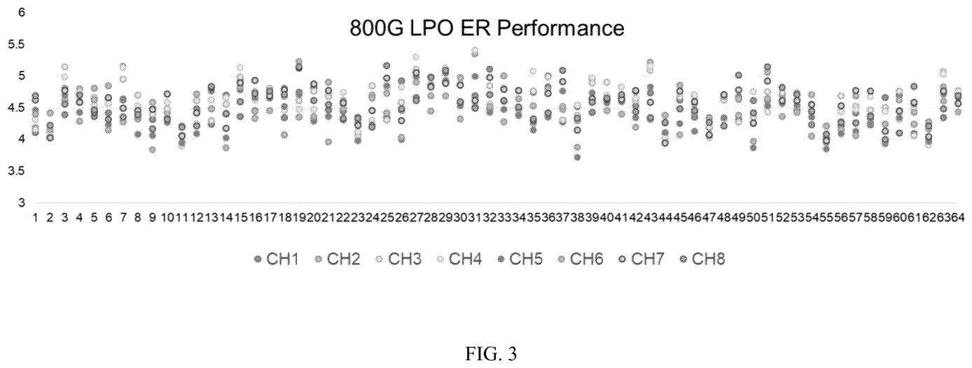

In the embodiments of this application, since the automatic gain control target value is dynamically adjusted based on the insertion loss value, the issue of inconsistent extinction ratios at ports with different insertion losses due to a fixed automatic gain control target value can be avoided. It automatically adapts to different insertion loss conditions without manual intervention, thus ensuring that the extinction ratios at each port remain essentially consistent. Referring to FIG. 3, FIG. 3 shows the extinction ratio data of all ports of a certain switch after applying the automatic gain control method described above. In FIG. 3, CH1-CH8 denote different channel ports. As can be seen from FIG. 3, after the switch adopts the automatic gain control method provided in this embodiment, the extinction ratio error of each channel on all ports of the switch can be remained within 1 dB, and the extinction ratio value of all ports is greater than 3.5 dB, satisfying the protocol requirements.

In addition, by using the peak detection device described above, the high-frequency peak value (20G PKD) and low-frequency peak value (1G PKD) of the output signal at each port (or channel) with different insertion losses can be detected separately. Then, based on the data pattern of peak values at different frequencies for ports with different insertion losses, the insertion loss value of different ports can be characterized, as shown in Table 1.

TABLE 1
High-frequency PKD test values and low-frequency PKD test values
corresponding to different insertion losses of a switch

| | Insertion | Driver | Extinction | 1G PKD | 20G PKD |
|---|---|---|---|---|---|
| Channel | loss (dB) | gain | ratio (dB) | (V) | (V) |
| CH1 | 6.42 | 5B80 | 4.559 | 0.3248 | 2.1274 |
| | 8.66 | 5CE0 | 4.506 | 0.3152 | 1.7516 |
| | 11.53 | 5DE0 | 4.362 | 0.2965 | 1.3414 |
| CH2 | 6.42 | 5D40 | 4.551 | 0.3317 | 2.1174 |
| | 8.66 | 5EA0 | 4.523 | 0.3144 | 1.8228 |
| | 11.53 | 5FE0 | 4.536 | 0.3059 | 1.4763 |
| CH3 | 6.42 | 5B80 | 4.5 | 0.3327 | 2.2177 |
| | 8.66 | 5CE0 | 4.56 | 0.3217 | 1.9473 |
| | 11.53 | 5DE0 | 4.379 | 0.3071 | 1.4386 |
| CH4 | 6.42 | 5D40 | 4.496 | 0.3323 | 2.2231 |
| | 8.66 | 5EA0 | 4.555 | 0.312 | 1.9285 |
| | 11.53 | 5FE0 | 4.654 | 0.3051 | 1.4788 |
| CH5 | 6.42 | 5C40 | 4.543 | 0.3439 | 2.1245 |
| | 8.66 | 5DA0 | 4.498 | 0.3233 | 1.8351 |
| | 11.53 | 5EE0 | 4.565 | 0.3187 | 1.5325 |

Table 1 records the experimental data obtained by maintaining a consistent extinction ratio under different insertion loss ports of a certain switch. According to Table 1, the 1G PKD reading remains basically unchanged with variations in insertion loss, while the 20G PKD reading decreases as the insertion loss increases. The ratio of the 1G PKD reading to the 20G PKD reading increases with increasing insertion loss; therefore, it can be used as a characterization value for the magnitude of the insertion loss.

The automatic gain control method, microcontroller unit, and automatic gain control system provided in this application integrate the peak detection device within the optical module, configured to detect the peak values of two different frequency signals. Based on the peak values detected by the peak detection device, the insertion loss value and the automatic gain control target value are calculated. Ultimately, the gain of the linear driver is adjusted to match the automatic gain control target value. This allows for signal attenuation caused by insertion loss to be compensated by adjusting the gain under environments with different insertion losses, thereby improving the consistency of the extinction ratio of each channel of a pluggable optical module.

What is claimed is:

1. An automatic gain control method, applied to a microcontroller unit in an automatic gain control system, wherein the automatic gain control system comprises a peak detection device, the automatic gain control method comprises:
after configuring and initializing the peak detection device in an optical module, and inserting the optical module into a target port of a network device, obtaining a peak value of the peak detection device at a preset frequency, wherein the peak value at the preset frequency comprises peak values at two frequencies;
calculating an insertion loss value based on the peak value at the preset frequency;
calculating an automatic gain control target value for the target port based on the insertion loss value; and
adjusting a gain of a linear driver with a goal of matching the automatic gain control target value.

2. The automatic gain control method according to claim 1, wherein the peak detection device comprises a first peak detection unit and a second peak detection unit, and the step of after configuring and initializing the peak detection device in an optical module, and inserting the optical module into a target port of a network device, obtaining a peak value of the peak detection device at a preset frequency comprises:
after configuring and initializing the peak detection device in the optical module, and inserting the optical module into the target port of the network device, obtaining a first peak value by the first peak detection unit detecting a low-frequency signal, and obtaining a second peak value by the second peak detection unit detecting a high-frequency signal.

3. The automatic gain control method according to claim 2, wherein a cutoff frequency of the first peak detection unit is 1 GHZ, and the step of obtaining a first peak value by the first peak detection unit detecting a low-frequency signal comprises:
obtaining the first peak value by detecting a low-frequency signal of 1 GHz through the first peak detection unit.

4. The automatic gain control method according to claim 2, wherein a center frequency of the second peak detection unit is 20 GHZ, and the step of obtaining a second peak value by the second peak detection unit detecting a high-frequency signal comprises:
obtaining the second peak value by detecting a high-frequency signal of 20 GHz through the second peak detection unit.

5. The automatic gain control method according to claim 1, wherein the step of calculating an insertion loss value based on the peak value at the preset frequency comprises:
determining a normalized difference between the peak values at the two frequencies; and
determining the insertion loss value based on the normalized difference.

6. The automatic gain control method according to claim 5, wherein the step of determining a normalized difference between the peak values at the two frequencies comprised in the peak value at the preset frequency comprises:
determining a difference value between the peak values at the two frequencies comprised in the peak value at the preset frequency; and
determining a ratio of the difference value to the peak value at a higher frequency among the two frequencies comprised in the peak value at the preset frequency, so as to obtain the normalized difference between the peak values at the two frequencies.

7. The automatic gain control method according to claim 1, wherein the step of calculating an automatic gain control target value for the target port based on the insertion loss value comprises:
obtaining a predetermined automatic gain control reference value; and
determining the automatic gain control target value of the target port based on the automatic gain control reference value and the insertion loss value.

8. The automatic gain control method according to claim 7, wherein the step of determining the automatic gain control target value of the target port based on the automatic gain control reference value and the insertion loss value comprises:
determining a target parameter based on a predetermined first adjustment coefficient, a predetermined second adjustment coefficient, and the insertion loss value, wherein the first adjustment coefficient and the second adjustment coefficient are used respectively as a weighting factor and a bias factor of the insertion loss value to calculate the target parameter; and
determining the automatic gain control target value of the target port based on the automatic gain control reference value and the target parameter, wherein the target parameter serves as a weighting factor of the automatic gain control reference value to calculate the automatic gain control target value.

9. The automatic gain control method according to claim 1, wherein the step of adjusting a gain of a linear driver with a goal of matching the automatic gain control target value comprises:
adjusting the gain of the linear driver based on the automatic gain control target value;
obtaining a new peak value of the peak detection device at the preset frequency;
calculating a new insertion loss value according to the new peak value at the preset frequency; and
determining whether the gain adjustment of the linear driver is completed based on the new insertion loss value.

10. A microcontroller unit, configured to execute the automatic gain control method according to claim 1.

11. An automatic gain control system, comprising a microcontroller unit and a peak detection device, wherein the peak detection device is configured to detect peak values of a target port at two frequencies, and the microcontroller unit is configured to execute the automatic gain control method according to claim 1 based on the peak values at the two frequencies.

12. The automatic gain control system according to claim 11, wherein the peak detection device comprises a photoelectric converter, a first peak detection unit, and a second peak detection unit;
input terminals of the first peak detection unit and the second peak detection unit are respectively electrically connected to output terminals of the photoelectric converter,
the first peak detection unit is configured to detect a low-frequency signal in an electrical signal output by the photoelectric converter converting an optical signal of the target port, so as to obtain a first peak, and
the second peak detection unit is configured to detect a high-frequency signal in the electrical signal output by the photoelectric converter converting the optical signal of the target port, so as to obtain a second peak.

13. The automatic gain control system according to claim 11, wherein the first peak detection unit comprises a low-pass filter and a first detection chip; and
the low-pass filter is configured to allow a low-frequency signal to pass, and the first detection chip is configured to detect a peak value of the low-frequency signal.

14. The automatic gain control system according to claim 12, wherein the second peak detection unit comprises a band-pass filter and a second detection chip; and
the band-pass filter is configured to allow a high-frequency signal to pass, and the second detection chip is configured to detect a peak value of the high-frequency signal.
